(19) United States
(12) Patent Application Publication
(10) Pub. No.: US 2024/0387573 A1
(43) Pub. Date: Nov. 21, 2024

(54) PHOTOELECTRIC CONVERSION APPARATUS AND PHOTOELECTRIC CONVERSION SYSTEM

(71) Applicant: CANON KABUSHIKI KAISHA, Tokyo (JP)

(72) Inventors: YASUSHI KOYAMA, Kanagawa (JP); YUKI KITAZAWA, Kanagawa (JP); TATSUYA MURAO, Kanagawa (JP); TAKAHIRO YAJIMA, Kanagawa (JP)

(21) Appl. No.: 18/664,983

(22) Filed: May 15, 2024

(30) Foreign Application Priority Data
May 19, 2023 (JP) 2023-083185

(51) Int. Cl. H01L 27/146

(52) U.S. Cl. CPC H01L 27/1461; H01L 27/14623; H01L 27/14627; H01L 27/14629; H01L 27/14636

(57) ABSTRACT

A photoelectric conversion n apparatus includes a semiconductor layer having a first surface and a second surface; an avalanche photodiode arranged in the semiconductor layer, an electrode film arranged to contact the first surface such that a Schottky barrier diode is formed in a contact portion with the semiconductor layer; and a wiring structure arranged on a side of the second surface.

### BACKGROUND

### Technical Field

The aspect of the embodiments relates to a photoelectric conversion apparatus and a photoelectric conversion system.

### Description of the Related Art

There is known a photodetector using an avalanche photodiode. Japanese Patent Laid-Open No. 2018-201005 discloses a photodetector in which a sensor chip including an avalanche photodiode and a logic chip including a circuit for processing a signal output from the avalanche photodiode are stacked. The avalanche photodiode includes an n-type semiconductor region and a p-type semiconductor region arranged under the n-type semiconductor region. The p-type semiconductor region includes a multiplication region where carriers generated by the incidence of detected light are avalanche-multiplied.

It is difficult for the photodetector described in Japanese Patent Laid-Open No. 2018-201005 to improve sensitivity to the infrared range, for example, the shortwave infrared range.

### SUMMARY

One of aspects of the embodiments provides a photoelectric conversion n apparatus comprising: a semiconductor layer having a first surface and a second surface; an avalanche photodiode arranged in the semiconductor layer; an electrode film arranged to contact the first surface such that a Schottky barrier diode is formed in a contact portion with the semiconductor layer; and a wiring structure arranged on a side of the second surface.

Further features of the disclosure will become apparent from the following description of exemplary embodiments with reference to the attached drawings.

### BRIEF DESCRIPTION OF THE DRAWINGS

FIG. 1 is a view showing an example of the arrangement of a photoelectric conversion apparatus according to an embodiment;

FIG. 2 is a view showing an example of the arrangement of the first substrate;

FIG. 3 is a view showing an example of the arrangement of the second substrate;

FIG. 4 is a circuit diagram showing an example of the arrangement of a pixel and a signal processing unit;

FIGS. 5A to 5C are a circuit diagram and timing charts for explaining a photon detection operation;

FIG. 6 is a plan view showing pixels according to the first embodiment;

FIG. 7 is a sectional view showing the pixels according to the first embodiment;

FIG. 8A is a sectional view showing pixels according to the second embodiment;

FIG. 8B is a sectional view showing the pixels according to the second embodiment;

FIG. 9 is a sectional view showing pixels according to a modification of the second embodiment;

FIG. 10 is a sectional view showing pixels according to a modification of the second embodiment;

FIG. 11 is a sectional view showing pixels according to a modification of the second embodiment;

FIG. 12A is a sectional view showing pixels according to the third embodiment;

FIG. 12B is a sectional view showing the pixels according to the third embodiment;

FIG. 13 is a sectional view showing pixels in another arrangement example according to the third embodiment;

FIG. 14 is a sectional view showing pixels in still another arrangement example according to the third embodiment;

FIG. 15 is a table showing an example of design according to the third embodiment;

FIG. 16 is a view for explaining the fourth embodiment;

FIG. 17 is a circuit diagram for explaining the fifth embodiment;

FIG. 18 is a view showing an example of the configuration of a photoelectric conversion system;

FIGS. 19A and 19B are views showing an example of the configuration of a photoelectric conversion system; and

FIG. 20 is a view showing an example of the configuration of a photoelectric conversion system.

### DESCRIPTION OF THE EMBODIMENTS

Hereinafter, embodiments will be described in detail with reference to the attached drawings. Note, the following embodiments are not intended to limit the scope of the disclosure. Multiple features are described in the embodiments, but limitation is not made to an aspect of the embodiments that requires all such features, and multiple such features may be combined as appropriate. Furthermore, in the attached drawings, the same reference numerals are given to the same or similar configurations, and redundant description thereof is omitted.

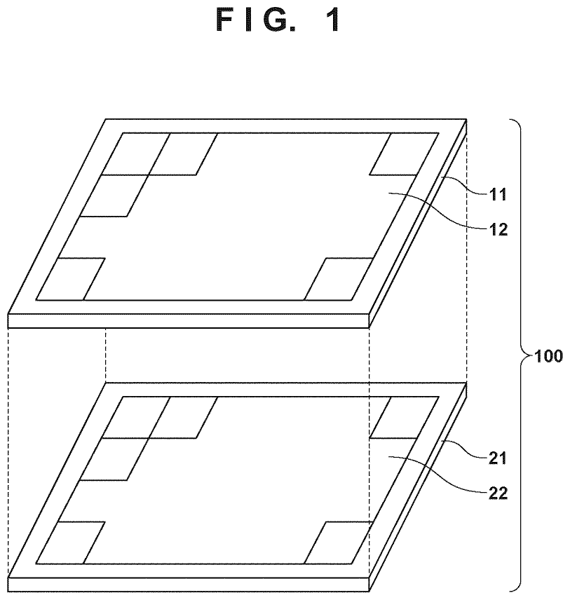

FIG. 1 schematically shows an example of the arrangement of a photoelectric conversion apparatus 100 according to an embodiment of the present disclosure. The photoelectric conversion apparatus 100 can have a structure in which a first substrate 11 and a second substrate 21 are stacked. The first substrate 11 can include a pixel array 12. The second substrate 21 can include a processing circuit 22 that processes a signal output from the pixel array 12.

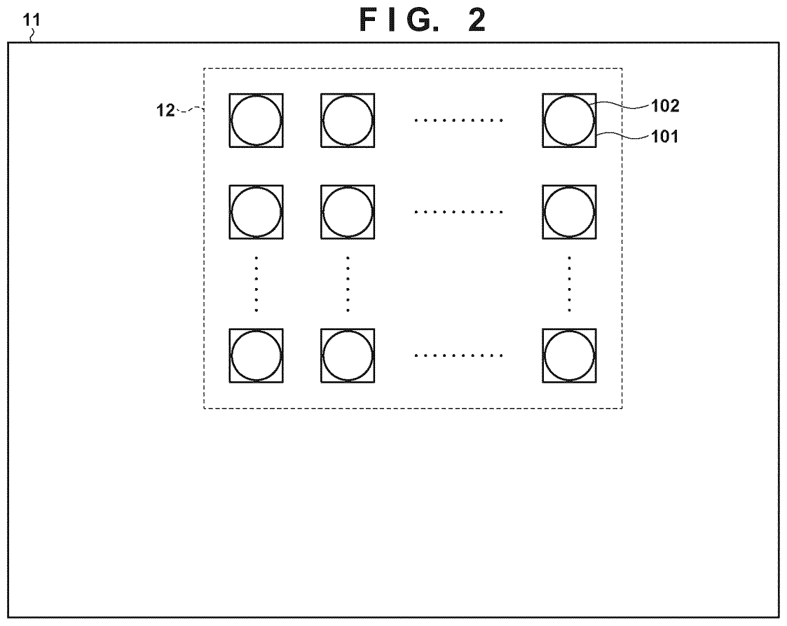

FIG. 2 schematically shows an example of the arrangement of the first substrate 11. The pixel array 12 of the first substrate 11 can include a plurality of pixels 101 arranged to form a plurality of rows and a plurality of columns. Each pixel 101 can include a photoelectric conversion unit 102. Each photoelectric conversion unit 102 includes an avalanche photodiode (to be also referred to as an APD hereinafter) and a Schottky barrier diode (to be also referred to as an SBD hereinafter) which are series-connected. The arrangement including the series-connected APD and SBD is advantageous in improving sensitivity to the infrared range, for example, the shortwave infrared range. The photoelectric conversion apparatus 100 will exemplarily be described below as an image capturing apparatus. However, the photoelectric conversion apparatus 100 may be formed as another apparatus. For example, the photoelectric conversion apparatus 100 can be formed as a distance measurement apparatus (for example, a distance measurement apparatus using a focus detection apparatus or TOF (Time Of Flight)) or a photometric apparatus (an apparatus for, for example, measuring an incident light amount). Note that the plurality of pixels 101 may linearly be arranged. In this case, the photoelectric conversion apparatus 100 can form a line sensor. It is defined that each pixel 101 includes the photoelectric conversion unit 102. Note that the pixel 101 can be referred to as a unit cell and the pixel array 12 can be referred to as a unit cell array.

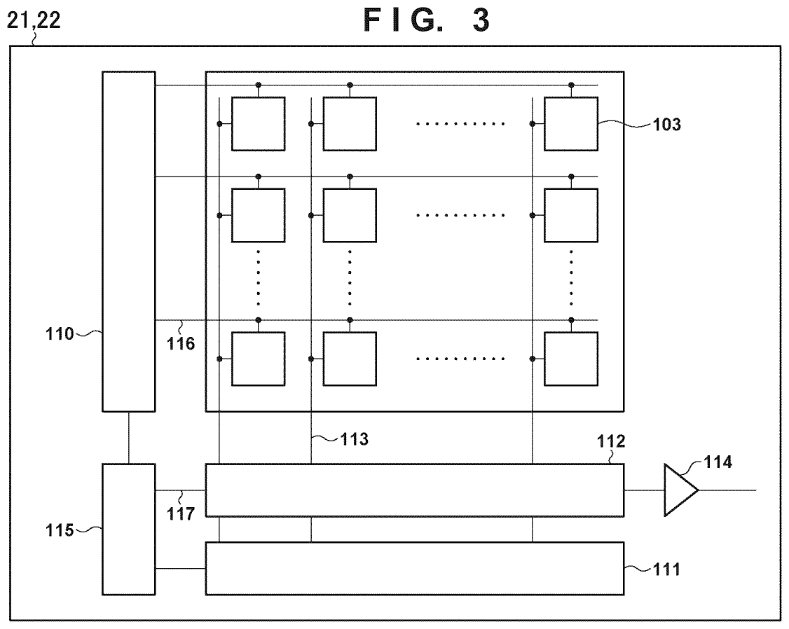

FIG. 3 schematically shows the arrangement of the processing circuit 22 of the second substrate 21. The processing circuit 22 can include, for example, a plurality of signal processing units 103, a readout circuit 112, a control unit 115, a horizontal scanning circuit 111, a plurality of signal lines 113, a vertical scanning circuit 110, and an output unit 114. Each signal processing unit 103 processes a signal output from the pixel 101. One signal processing unit 103 may be provided for one pixel 101, or one signal processing unit 103 may be provided for two or more pixels 101. In an example, one pixel 101 and one signal processing unit 103 can electrically be connected by a connection portion. The signal processing unit 103 can include, for example, a counter and a memory. The memory can hold a count value obtained by counting by the counter. A concrete arrangement of the connection portion is, for example, a structure in which conductor patterns of copper or the like are bonded, a structure using a micro-bump, or a structure in which a through electrode is provided.

For example, the vertical scanning circuit 110 can sequentially select a plurality of rows of the pixel array 12 in accordance with a control signal supplied from the control unit 115. The vertical scanning circuit 110 can supply a control signal to the pixel array 12 via a plurality of control signal lines 116. The vertical scanning circuit 110 can include, for example, at least one of a shift register and an address decoder. The readout circuit 112 reads out signals output, via the plurality of signal lines 113, from the signal processing units 103 corresponding to the pixels 101 of the row selected by the vertical scanning circuit 110. For example, the horizontal scanning circuit 111 supplies to the output unit 114, in a predetermined order, the signals for one row read out by the readout circuit 112.

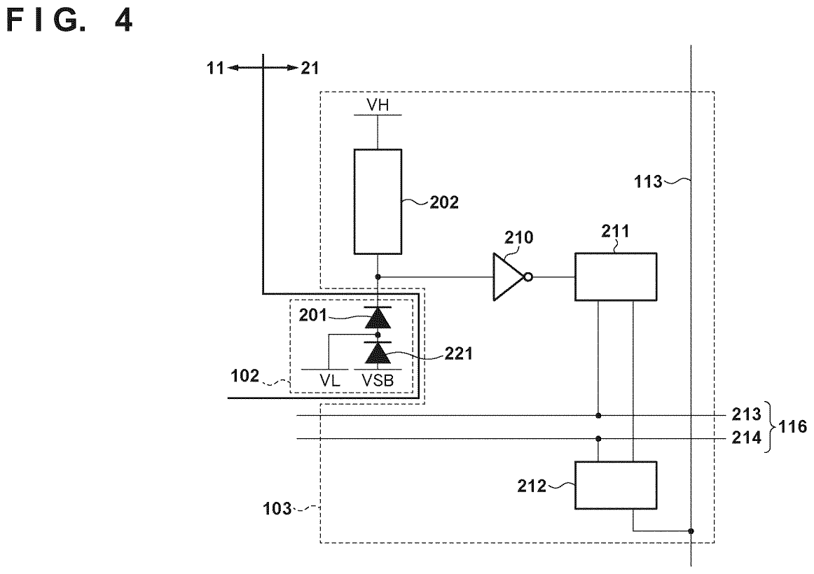

FIG. 4 shows an example of the arrangement of the photoelectric conversion unit 102 and the signal processing unit 103. In the example shown in FIG. 4, one signal processing unit 103 is assigned to one photoelectric conversion unit 102. The photoelectric conversion unit 102 includes an APD 201 and an SBD 221 which are series-connected. As described above, the photoelectric conversion unit 102 is arranged on the first substrate 11, and the signal processing unit 103 is arranged on the second substrate 21. However, at least one of a plurality of components of the signal processing unit 103 may be arranged on the first substrate 11. Alternatively, all the plurality of components of the signal processing unit 103 may be arranged on the first substrate 11. A solid line is a boundary between the first substrate 11 and the second substrate 21, and indicates the position of a junction portion. In this embodiment, one photoelectric conversion unit 102 and one signal processing unit 103 are paired.

A first potential VL can be applied to the anode of the APD 201, and a second potential VH can be applied to the cathode of the APD 201. The second potential VH is a potential higher than the first potential VL. That is, a potential difference between the first potential VL and the second potential VH is applied to the APD 201 (between the anode and cathode of the APD 201). This potential difference is a reverse bias voltage that causes the APD 201 to perform an avalanche multiplication operation. Charges generated by photons entering the APD 201 cause avalanche multiplication, thereby generating an avalanche current. A third potential VSB can be applied to the anode of the SBD 221 and the first potential VL can be applied to the cathode of the SBD 221. A mode of applying a voltage higher than the breakdown voltage of the APD 201 between the anode and cathode of the APD 201 is called a Geiger mode. A mode of applying a voltage around or lower than the breakdown voltage between the anode and cathode of the APD 201 is called a linear mode. An APD operating in the Geiger mode can be called a Single Photon Avalanche Diode (SPAD). In an example, the first potential VL is −30 V, the second potential VH is 1 V, and the third potential VSB is −31 V.

The signal processing unit 103 can include a quenching element 202 connected between the cathode of the APD 201 and a terminal supplied with the second potential VH. The quenching element 202 has a function of converting the change of the avalanche current generated in the APD 201 into a voltage signal. The quenching element 202 functions as a load circuit (quenching circuit) at the time of signal multiplication by avalanche multiplication, and serves to suppress avalanche multiplication by suppressing the voltage applied to the APD 201. This is known as a quenching operation.

The signal processing unit 103 can additionally include, for example, at least one of a waveform shaping unit 210, a counter circuit 211, and a selection circuit 212. The waveform shaping unit 210 can output a pulse signal by shaping the potential change of the cathode of the APD 201 at the time of detection of a photon. The waveform shaping unit 210 can include, for example, an inverter circuit. In the example shown in FIG. 4, the waveform shaping unit 210 is formed by one inverter but the waveform shaping unit 210 may be formed by series-connecting a plurality of inverters or by another circuit having the waveform shaping effect.

The counter circuit 211 can be configured to count a pulse signal output from the waveform shaping unit 210 and hold a count value obtained by counting. When a control pulse pRES of an active level is supplied from the vertical scanning circuit 110 via a driving line 213, the signal held in the counter circuit 211 can be reset. When a control pulse pSEL of an active level is supplied from the vertical scanning circuit unit 110 via a driving line 214, the selection circuit 212 can electrically connect the counter circuit 211 and the signal line 113. The selection circuit 212 can include, for example, a buffer circuit.

In this example, the counter circuit 211 is provided. However, the photoelectric conversion apparatus 100 may be configured to acquire a pulse detection timing by providing a Time-to-Digital Converter (to be referred to as a TDC hereinafter), instead of the counter circuit 211. In this case, the generation timing of the pulse signal output from the waveform shaping unit 210 can be converted into a digital signal by the TDC. A control pulse pREF (reference signal) can be supplied from the vertical scanning circuit unit 110 to the TDC via a driving line to measure the timing of the pulse signal. With reference to the control pulse pREF, the TDC can generate a digital signal corresponding to the generation timing of the pulse signal output from the waveform shaping unit 210.

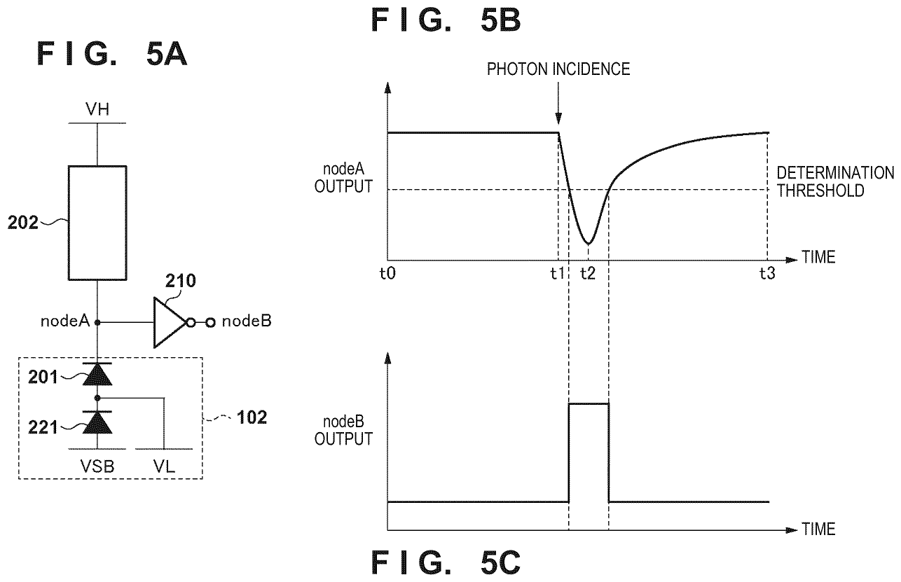

FIGS. 5A to 5C are a circuit diagram and timing charts for explaining a photon detection operation by the photoelectric conversion apparatus 100. FIG. 5A is a circuit diagram showing an excerpt of the APD 201, the SBD 221, the quenching element 202, and the waveform shaping unit 210 from FIG. 4. The input side of the waveform shaping unit 210 is a node A and the output side of the waveform shaping unit 210 is a node B. FIG. 5B shows the waveform at the node A of FIG. 5A and FIG. 5C shows the waveform at the node B of FIG. 5A. From time t0 to time t1, a potential difference of VH-VSB is applied to the photoelectric conversion unit 102 including the APD 201 and the SBD 221.

A potential difference of VH-VL is applied to the APD 201, and a potential difference of VL-VSB is applied to the SBD 221. When a photon enters at time t1, the SBD 221 generates a charge pair by photoelectric conversion, and avalanche multiplication occurs in the APD 201 in response to the charge pair. This causes an avalanche multiplication current to flow into the quenching element 202, and the voltage (potential) of the node A drops. When the voltage drop amount increases and the potential difference applied to the APD 201 decreases, the avalanche multiplication of the APD 201 stops. After that, a current compensating for the voltage drop from the voltage VL flows into the node A, and the node A is statically determined at the original potential level at time t3. At this time, a portion at which the output waveform exceeds a given threshold at the node A is waveform-shaped by the waveform shaping circuit 210 and a pulse signal appears at the node B.

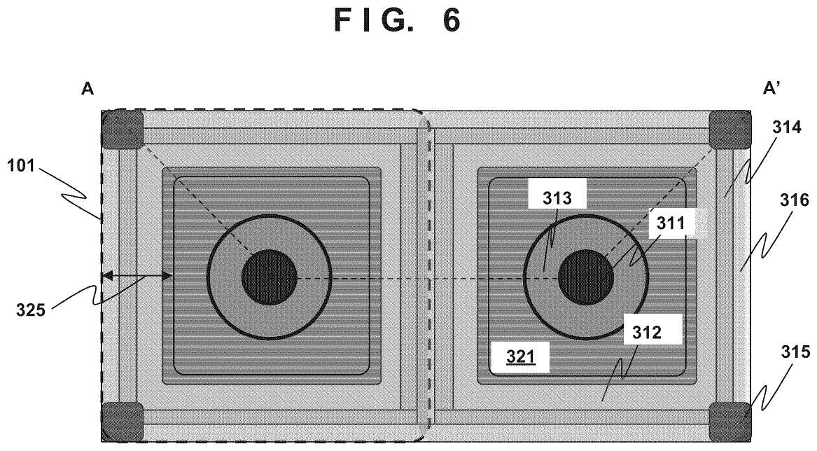

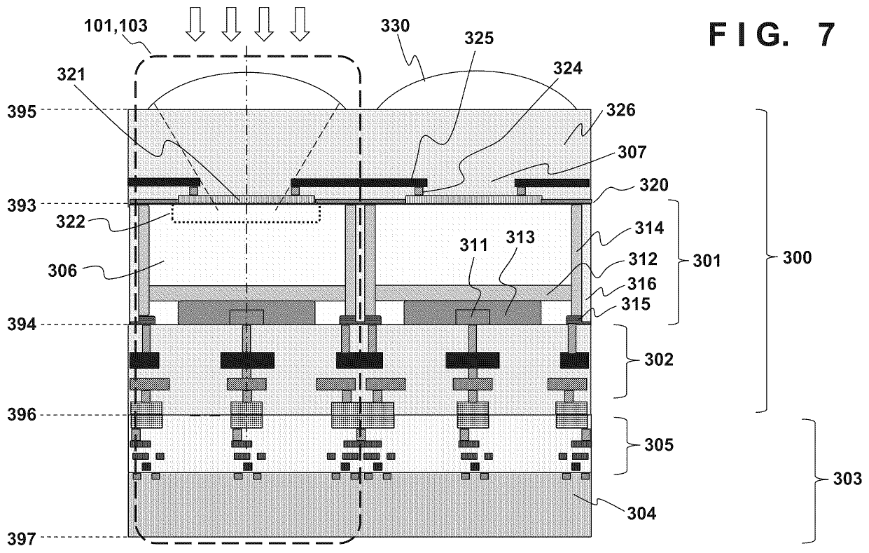

FIGS. 6 and 7 schematically show a structure of the photoelectric conversion apparatus 100 for two pixels according to the first embodiment. FIG. 6 is a plan view. Note that a plan view is synonymous with an orthogonal projection to a first surface 393 or a second surface 394 to be described below, and is also called a planar view. FIG. 7 is a sectional view taken along a line A-A′ in FIG. 6. In FIGS. 6 and 7, a region surrounded by dotted lines represents one pixel 101 and the signal processing unit 103 corresponding to the pixel.

The photoelectric conversion apparatus 100 can include a first semiconductor layer (for example, a silicon layer) 301 having the first surface 393 and the second surface 394. The photoelectric conversion apparatus 100 can include a first wiring structure 302 having the second surface 394 and a fourth surface 396. The first wiring structure 302 can include at least one wiring layer each including a conductive pattern, and a plug electrically connected to the conductive pattern. The first wiring structure 302 is arranged on the side of the second surface 394 (second surface side). The second surface 394 can be shared by the first semiconductor layer 301 and the first wiring structure 302. Alternatively, the second surface 394 can be the interface between the first semiconductor layer 301 and the first wiring structure 302. The first semiconductor layer 301 and the first wiring structure 302 can form a first substrate 300. The first substrate 300 may be understood to further include an electrode film 321 and a sealing layer 326 to be described later. The sealing layer 326 has a third surface 395 on the opposite side of the first surface 393, and a microlens 330 can be arranged on the third surface 395.

The photoelectric conversion apparatus 100 can include a second substrate 303 having the fourth surface 396 and a fifth surface 397. The second substrate 303 can include a second semiconductor layer (for example, a silicon layer) 304 and a second wiring structure 305. The second wiring structure 305 can include at least one wiring layer each including a conductive pattern, and a plug electrically connected to the conductive pattern. The second semiconductor layer 304 can have the fifth surface 397. The second wiring structure 305 can have the fourth surface 396. The fourth surface 396 can be shared by the first wiring structure 302 and the second wiring structure 305. Alternatively, the fourth surface 396 can be the interface between the first wiring structure 302 and the second wiring structure 305.

The fourth surface 396 can be a junction surface. From another viewpoint, the second wiring structure 305 can be arranged between the first wiring structure 302 and the second semiconductor layer 304.

The photoelectric conversion apparatus 100 can include the electrode film 321 arranged to contact the first surface 393 of the first semiconductor layer 301. The first semiconductor layer 301 can include a semiconductor region 306 that forms at least part of the first surface 393. At least part of light from the outside of the photoelectric conversion apparatus 100 can enter the first semiconductor layer 301 through the electrode film 321. The electrode film 321 is arranged to contact the first surface 393 such that the Schottky barrier diode 221 is formed in a contact portion with the semiconductor region 306 of the first semiconductor layer 301.

The avalanche photodiode (APD) 201 can be arranged between the second surface 394 and the Schottky barrier diode (SBD) 221. In an orthogonal projection to the second surface 394, the avalanche photodiode 201 and the Schottky barrier diode 221 can overlap each other. The electrode film 321 can be applied with a potential to form a depletion region 322 in the first semiconductor layer 301. The avalanche photodiode 201 and the Schottky barrier diode 221 are series-connected via the depletion region 322.

The photoelectric conversion apparatus 100 can further include a light shielding film 325. The light shielding film 325 can be a metal film. The light shielding film 325 can be arranged so that the first surface 393 is located between the second surface 394 and the light shielding film 325. The light shielding film 325 includes an opening 307 that defines light entering the Schottky barrier diode 221. The light shielding film 325 can electrically be connected to the electrode film 321. For example, the light shielding film 325 can electrically be connected to the electrode film 321 via a plug 324.

The electrode film 321 and the light shielding film 325 can be covered with the sealing layer 326. The sealing layer 326 can have the third surface 395. A microlens 330 can be arranged on the sealing layer 326. The sealing layer 326 can include, for example, a color filter, a planarization film, and a protection film made of an inorganic material. At least part of the third surface 395 can be shared by the sealing layer 326 and the microlens 330. Alternatively, at least part of the third surface 395 can be the interface between the sealing layer 326 and the microlens 330. The microlens 330 may be integrated with the sealing layer 326. In this case, the third surface 395 can include a point at which two microlenses 330 contact each other. Light from the outside of the photoelectric conversion apparatus 100 can enter the first semiconductor layer 301 through the microlens 330, the sealing layer 326, and the electrode film 321.

The avalanche photodiode 201 can include the first semiconductor region 311 of the first conductivity type and a second semiconductor region 312 of the second conductivity type. In addition, the avalanche photodiode 201 can include a third semiconductor region 313 of the first conductivity type arranged between the second surface 394 and the second semiconductor region 312. In an example, the first conductivity type is an n type and the second conductivity type is a p type, and vice versa. The third semiconductor region 313 can include a portion arranged between the second surface 394 and the second semiconductor region 312 to surround the side surface of the first semiconductor region 311, and a portion arranged between the first semiconductor region 311 and the second semiconductor region 312. The semiconductor region 306 as part of the first semiconductor layer 301 may be a semiconductor region of the first conductivity type or a semiconductor region of the second conductivity type. In one embodiment, in the semiconductor region 306, the impurity concentration (net concentration) of the second conductivity type is lower than those in the second semiconductor region 312 and a fourth semiconductor region 314. In a direction along the first surface 393, the dimension of a region where the electrode film 321 contacts the first surface 393 is preferably larger than the dimension of the first semiconductor region 311.

The photoelectric conversion apparatus 100 can further include the fourth semiconductor region 314 of the second conductivity type. The fourth semiconductor region 314 is electrically connected to the second semiconductor region 312, and extends between the first surface 393 and the second surface 394 in a direction orthogonal to the first surface 393. A potential can be applied to the second semiconductor region 312 via the fourth semiconductor region 314. The fourth semiconductor region 314 can be arranged to surround the first semiconductor region 311, the second semiconductor region 312, and the third semiconductor region 313. A fifth semiconductor region 315 of the second conductivity type can be arranged between the second surface 394 and the fourth semiconductor region 314. The impurity concentration of the second conductivity type in the fifth semiconductor region 315 is higher than that in the fourth semiconductor region 314.

The photoelectric conversion apparatus 100 can further include a pinning film 320 that covers the first surface 393. The pinning film 320 can be, for example, an insulating film made of at least one of hafnium oxide, zirconium oxide, aluminum oxide, titanium oxide, and tantalum oxide. The pinning film 320 includes an opening, and the electrode film 321 can be arranged to contact the first surface 393 via the opening of the pinning film 320. The light shielding film 325 includes the opening 307 that defines light entering the Schottky barrier diode 221. The light shielding film 325 and the electrode film 321 can electrically be connected by the plug 324. The electrode film 321 may include a region that covers the pinning film 320, and the plug 324 may be connected to the electrode film 321 within the region.

The first surface 393 of the first semiconductor layer 301 can be sealed by the pinning film 320. The electrode film 321 can contact the semiconductor region (for example, silicon) 306 of the first semiconductor layer 301 via the opening of the pinning film 320, thereby forming a Schottky junction portion. The electrode film 321 is made of a material that forms the Schottky junction portion by the semiconductor region 306 and the electrode film 321. The electrode film 321 can be made of, for example, a metal, a metal silicide, or a metal oxide. In the Schottky junction portion, a Schottky barrier arising from a difference in work function between the semiconductor region 306 and the electrode film 321 is formed. The height of the Schottky barrier, in one embodiment, is equal to or smaller than ½ of the bandgap of the semiconductor region 306 constituting the first semiconductor layer 301. When the Schottky junction portion of the Schottky barrier diode 221 is irradiated with light (a wavelength of 0.8 to 30 μm) of the infrared wavelength range having energy exceeding the height of the Schottky barrier, electrons or holes climb up the Schottky barrier to reach the depletion region 322.

As the material of the electrode film 321 constituting the Schottky barrier diode, the following metal materials, metal silicides, metal oxides, and the like can preferably be used. As the metal materials, ytterbium (Yb), aluminum (Al), manganese (Mn), bismuth (Bi), tin (Sn), antimony (Sb), lead (Pb), hafnium (Hf), zirconia (Zr), silver (Ag), titanium (Ti), and the like can preferably be used as materials having sensitivity in a wavelength band of 1,550 to 1,800 nm (0.7 to 0.8 eV). In addition, nickel (Ni), iron (Fe), gold (Au), palladium (Pd), platinum (Pt), and the like are suitable as materials having sensitivity in a wavelength band of 2,000 to 2,500 nm (0.5 to 0.6 eV).

As the metal silicide as a compound of silicon and a metal, yttrium silicide (YSi₂) can be used as a material having sensitivity at a wavelength of 1,550 nm (0.75 eV), and Zirconium silicide (ZrSi₂), hafnium silicide (HfSi), nickel silicide (NiSi, NiSi₂), titanium silicide (TiSi₂), cobalt silicide (CoSi₂), manganese silicide (MnSi), and the like can be used as materials having sensitivity at a wavelength of 2,500 to 3,000 nm (0.4 to 0.5 eV). Furthermore, iridium silicide (IrSi) and platinum silicide (PtSi, Pt₂Si) can be used as materials having sensitivity at a wavelength of 4,000 to 6,000 nm (0.2 to 0.3 eV).

As the metal oxide, an oxide semiconductor as a metal oxide such as indium tin oxide (ITO), indium zinc oxide (IZO), zinc oxide (ZnO), indium gallium zinc oxide (IGZO), tin oxide (SnO₂), titanium oxide (TiO₂), and molybdenum oxide (MoO₂) can be used.

Light entering the Schottky junction interface between the electrode film 321 and the semiconductor region 306 is photoelectrically converted, thereby generating charges. The electrode film 321, in embodiment, is thus semi-transparent or transparent (light transmittance of, for example, about 1% to 100%) at the wavelength of received light. Therefore, the thickness of the electrode film 321 can be set to be equal to or smaller than a wavelength λ of received light, and preferably equal to or smaller than λ/10. The thickness of the electrode film 321 can typically be adjusted to a thickness of 100 nm or less. In a plan view (an orthogonal projection to the first surface 393), the electrode film 321 has a rectangular shape, and can be arranged on the first surface 393 of the first semiconductor layer 301. In a peripheral portion within the region of the electrode film 321, the plug 324 that electrically connects the light shielding film 325 and the electrode film 321 can be arranged.

The sealing layer 326 can be arranged to cover the electrode film 321. The light shielding film 325 for blocking stray light can be arranged between the electrode film 321 and the third surface 395 as the upper surface of the sealing layer 326. The light shielding film 325 includes the opening 307, and light enters the electrode film 321 via the opening 307.

The opening 307 is arranged to overlap the electrode film 321. The light shielding film 325 can be used to apply a potential to the electrode film 321. The light shielding film 325 can be supplied with the third potential VSB via a conductive path (not shown). The third potential VSB can be supplied from the light shielding film 325 to the electrode film 321 via the plug 324. This forms the depletion region 322 inside the semiconductor region 306. The width of the opening 307 may be smaller than that of the electrode film 321. The area of the opening 307 may be smaller than that of the electrode film 321.

The microlens 330 can be stacked on the side of the third surface 395 of the sealing layer 326. The amount of light obtained by collecting incident light in the direction of the SBD 221 and the APD 201 and photoelectrically converting it can be increased by arranging the microlens 330 at the center of the pixel. This can improve the sensitivity of the photoelectric conversion apparatus 100. Light entering from the side of the third surface 395 is collected by the microlens 330, passes through the sealing layer 326 and the opening 307, and reaches the Schottky barrier diode 221 formed on the first surface 393 of the semiconductor region 306 constituting the first semiconductor layer 301. The light that has reached the depletion region 322 generates charges, and the charges are diffused inside the semiconductor region 306 of the first semiconductor layer 301 by an electric field applied to the Schottky barrier diode 221, and reach the second semiconductor region 312 of the second conductivity type.

The first semiconductor region 311 of the first conductivity type functions as the cathode of the APD 201, and is applied with the second potential VH. The fifth semiconductor region 315 of the second conductivity type functions as the anode of the APD 201, and is applied with the first potential VL. The first potential VL is applied to the second semiconductor region 312 of the second conductivity type via the fourth semiconductor region 314 of the second conductivity type. This forms an avalanche multiplication region in a region where the first semiconductor region 311 of the first conductivity type and the second semiconductor region 312 of the second conductivity type are close to each other. When charges (that can include charges generated by the SBD 221) generated by incident light pass through the avalanche region, they cause avalanche multiplication, generating an avalanche current. The fourth semiconductor region 314 of the second conductivity type can also function as an isolation region between the adjacent pixels. The fifth semiconductor region 315 of the second conductivity type can function to reduce a contact resistance between the first semiconductor layer 301 and a conductive member (for example, a plug) arranged in the first wiring structure 302. The impurity concentration of the second conductivity type is higher in the fifth semiconductor region 315 than in the fourth semiconductor region 314. An isolation trench 316 may be arranged between the fourth semiconductor region 314 of one pixel and the fourth semiconductor region 314 of its adjacent pixel. The isolation trench 316 is advantageous in reducing crosstalk between the adjacent pixels. The third semiconductor region 313 of the first conductivity type can be arranged to cover the corner portion of the first semiconductor region 311 of the first conductivity type, thereby suppressing a local high electric field region from being formed between the first semiconductor region 311 of the first conductivity type and the fifth semiconductor region 315 of the second conductivity type. The isolation trench 316 can be a groove or a through hole provided in the first semiconductor layer 301. A pinning layer, an air gap, an insulating layer containing a dielectric, a layer made of an opaque material for light shielding, and the like can be arranged inside the isolation trench 316.

The second substrate 303 on which the plurality of signal processing units 103 are arranged can form imaging data in the infrared wavelength band based on signals output from the plurality of pixels of the first substrate 300. The photoelectric conversion apparatus 100 exemplified in FIG. 7 is of a backside illumination type in which light enters the first surface 393 as the back surface of the semiconductor layer 301, and the SBD 221 is arranged on the back surface side of the semiconductor layer 301. This improves efficiency of photoelectric conversion in the infrared wavelength band, thereby making it possible to improve sensitivity to the infrared wavelength band and miniaturize the pixels.

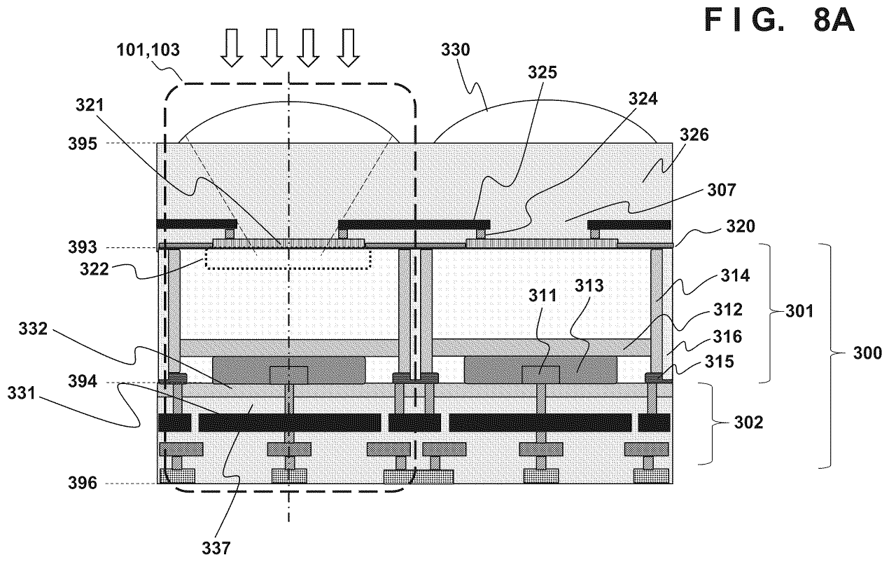

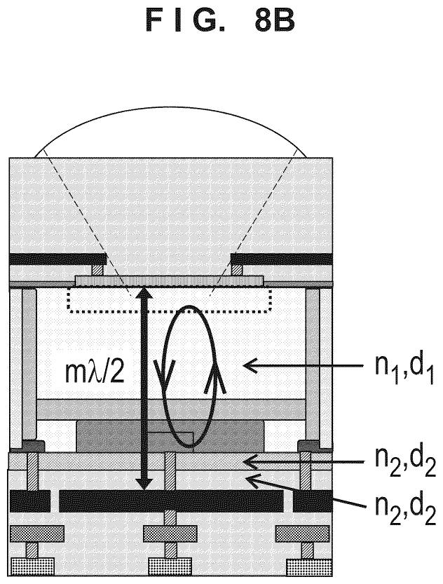

The second embodiment of the present disclosure will be described below. Matters not mentioned as the second embodiment can comply with the first embodiment. FIGS. 8A and 8B show the sectional structure of the arrangement of a photoelectric conversion apparatus 100 for two pixels according to the second embodiment. FIG. 8A is a sectional view taken along a line A-A′ in FIG. 6. In the photoelectric conversion apparatus 100 according to the second embodiment, a first wiring structure 302 can include a first reflection layer 331 that reflects light having passed through a first semiconductor layer 301 and entered the first wiring structure 302. The first wiring structure 302 can include an adjustment layer 332 arranged between a second surface 394 and the first reflection layer 331. The adjustment layer 332 is an insulating layer for adjusting a distance L1 between an electrode film 321 and thee first reflection layer 331. As exemplified in FIG. 8A, the photoelectric conversion apparatus 100 may be formed by one substrate 300.

The first reflection layer 331 provides a reflection surface that reflects infrared rays having passed through the electrode film 321 and entered the first semiconductor layer 301 to reuse for photoelectrical conversion in a Schottky barrier diode 221. The first reflection layer 331 can be made of a metal material used in semiconductor integration technology. The first reflection layer 331 can be made of, for example, aluminum (Al) or copper (Cu). The first reflection layer 331 may serve as a signal line or a potential supply line (power supply line) in the first wiring structure 302. The first reflection layer 331 can function as, for example, part of a signal line electrically connected to the first semiconductor region 311 of the first conductivity type as the cathode of an APD 201. In a direction along the second surface 394, the dimension of the first reflection layer 331 may be larger than that of the electrode film 321. Alternatively, in a plane along the second surface 394, the area of the first reflection layer 331 may be larger than that of the electrode film 321. In this specification, the dimension and area of the electrode film 321 are those of a portion where the electrode film 321 contacts a first surface 393. The dimension of the first reflection layer 331 in the direction along the second surface 394 may be larger than that of a third semiconductor region 313 in the direction along the second surface 394. The dimension of the first reflection layer 331 in the direction along the second surface 394 may be larger than that of an opening 307 of a light shielding film 325 in the direction along the second surface 394.

Light having passed through the electrode film 321 and the first semiconductor layer 301 is reflected by the first reflection layer 331 to return to the SBD 221 formed by the electrode film 321 and a semiconductor region 306 of the first semiconductor layer 301, and is reused for photoelectric conversion at the Schottky junction interface. Therefore, by providing the first reflection layer 331, the photoelectric conversion efficiency can be improved. Assuming that an optical path length l1 corresponding to the distance L1 between the first reflection layer 331 and the electrode film 321 is an integer multiple of a half wavelength of received light, a standing wave is formed by optical interference. In this case, only light of a specific wavelength can be strengthened at the position of the Schottky junction interface of the SBD formed by the electrode film 321 and the semiconductor region 306. When λ represents the wavelength of received light (or light to be strengthened), the distance L1 and its corresponding optical path length l1 can be decided using the following equations. The distance L1 can be considered as a physical film thickness, and the optical path length l1 can be considered as an optical film thickness. In actual design, it is possible to consider an allowance with respect to l1, and obtain an appropriate effect by, for example, deciding the optical path length between the first reflection layer 331 and the electrode film 321 within the range of l1±λ/8. In a case where reflection by a second reflection layer 333 (to be described later) is used or a case where light of a given specific wavelength is intentionally weakened, the distance L1 may be decided to match m₁×λ/4. Note that an interlayer insulating layer 337 is an insulating layer between the first reflection layer 331 and the adjustment layer 332 in the first wiring structure 302.

$$L 1 = {d}_{1} + {d}_{2} + {d}_{3}$$

$$l 1 = {m}_{1} \times λ / 2 = {d}_{1} \times {n}_{1} + {d}_{2} \times {n}_{2} + {d}_{3} \times {n}_{3}$$

d₁: film thickness of semiconductor region 306
d₂: film thickness of adjustment layer 332
d₃: film thickness of interlayer insulating layer 337
n₁: refractive index of semiconductor layer 301
n₂: refractive index of adjustment layer 332
n₃: refractive index of interlayer insulating layer 337
m₁: natural number
λ : wavelength
L1: distance between first reflection layer 331 and electrode film 321
l1: optical path length between first reflection layer 331 and electrode film 321

For example, if the wavelength of the received light is 1 μm, in an example, the material of the semiconductor region 306 can be silicon (d₁=6000 nm and n₁=3.54), the material of the interlayer insulating layer 337 can be silicon oxide (d₃=300 nm and n₃=1.45), and the material of the adjustment layer 332 can be silicon nitride (d₂=165 nm and n₂=2.00). In this case, the distance (physical film thickness) is 6,465 nm, the optical path lenght l1 is 22,005 nm, and m₁=44, thereby causing light beams to strengthen each other near the electrode film 321. Therefore, the antinode of the standing wave of light having a wavelength of 1 μm coincides with the position of the electrode film 321, and the light having a wavelength of 1 μm is selectively, strongly received, thereby making it possible to attempt to increase sensitivity at this wavelength.

In a case where the photoelectric conversion apparatus 100 is formed as a SPAD sensor, in an example, the semiconductor region 306 can be made of silicon with a thickness of about 0.1 to 30 μm. For the interlayer insulating layer 337 and the adjustment layer 332, a dielectric such as SiO₂, SiNx, SiON, TiN, TiO₂, HfO₂, SiC, or Al₂O₃ is preferably used, and the film thickness of each layer can be about 0.1 to 3 μm. Assuming that the wavelength band of light detected by the photoelectric conversion apparatus 100 is about 800 nm to 30 μm, the distance (physical film thickness) L1 falls within the range of about 0.1 to 30 μm.

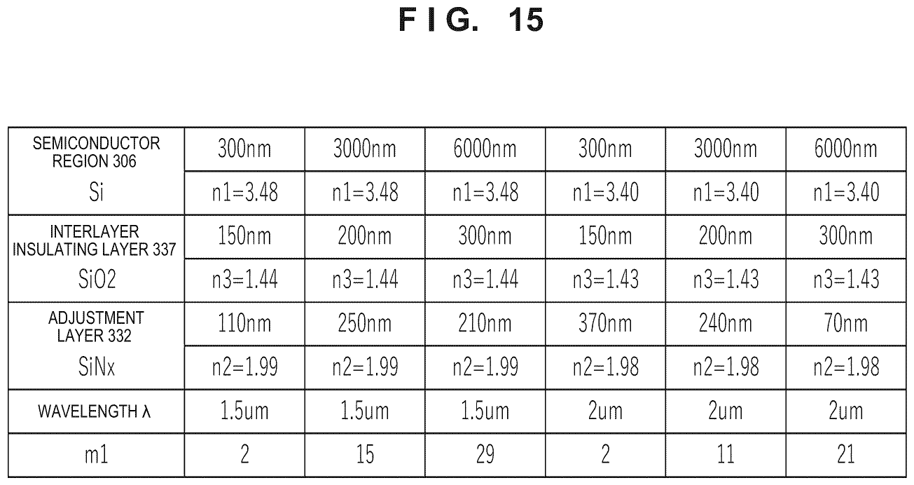

The structure of a conventional visible-light SPAD can be diverted to the arrangement in which silicon of the semiconductor region 306 is thick, thereby implementing an image sensor that can detect both the visible light band and the SWIR band. In a case where silicon of the semiconductor region 306 is thin, for example, d₁=3000 nm, when the thickness d₃ of SiO₂ as the interlayer insulating layer 337 is set to 200 nm, and the thickness d₂ of SiNx as the adjustment layer 332 is set to 50 nm, m₁=22 is obtained, thus obtaining a film thickness optimum for causing light beams to strengthen each other. In a case where sensitivity to the visible light band is unnecessary and only the IR band needs to be detected, silicon of the semiconductor region 306 is thinned. In a case where d₁=300 nm, when the thickness d₃ of SiO₂ as the interlayer insulating layer 337 is set to 150 nm, and the thickness d₂ of SiNx as the adjustment layer 332 is set to 110 nm, m₁=3 is obtained, thus obtaining a film thickness optimum for causing light beams having a wavelength of 1 μm to strengthen each other. To increase sensitivity at another wavelength in the IR band, each layer can be adjusted in correspondence with the wavelength, as shown in FIG. 15.

The arrangement in which the light shielding film 325 is arranged on the electrode film 321 is advantageous in attempting to reduce noise caused by stray light such as visible light. The arrangement in which the pinning film 320 is provided in a region other than the arrangement region of the electrode film 321 on the first surface 393 of each pixel is advantageous in reducing the Dark Count Rate (DCR). The arrangement in which the microlens 330 is arranged at the center of the pixel is advantageous in obtaining the uniform sensitivity distribution in the plurality of pixels by arranging the electrode film 321, the first reflection layer 331, and the opening 307 of the light shielding film 325 on the central axis, that is, in suppressing shading.

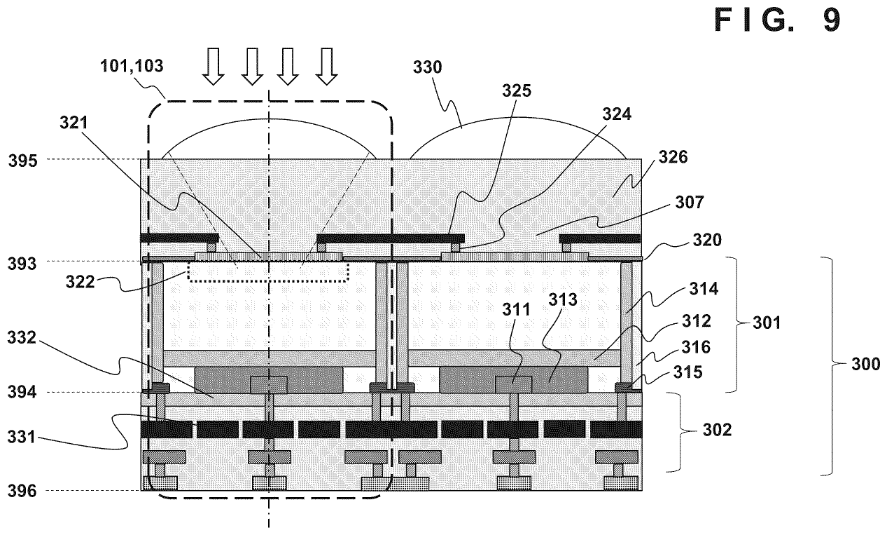

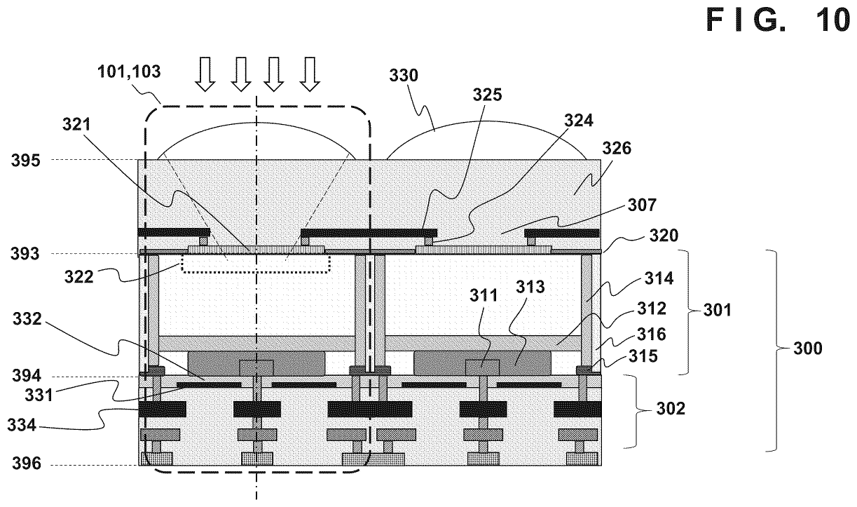

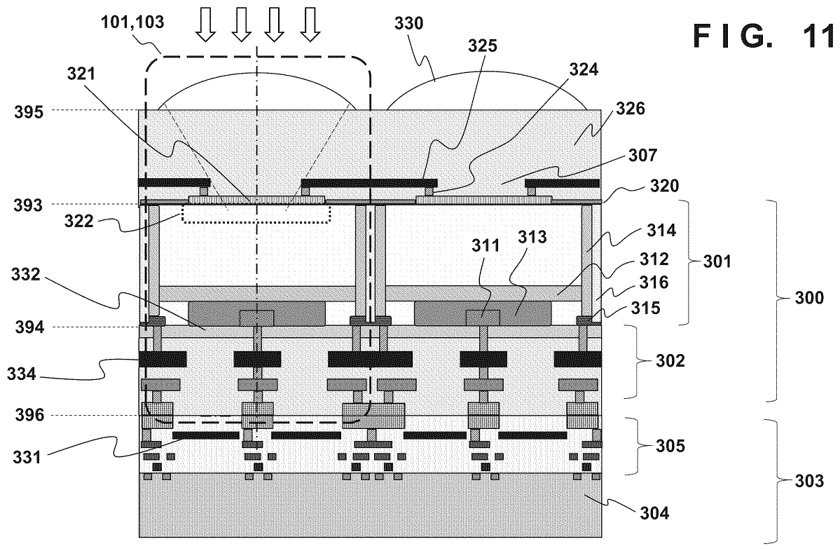

FIGS. 9, 10, and 11 each show a modification of the second embodiment. In an arrangement example shown in FIG. 9, the first reflection layer 331 is arranged in the same layer as that of signal lines in the wiring structure 302 but is electrically insulated from the signal lines. This arrangement is advantageous in reducing a timing jitter since a signal delay caused by a parasitic capacitance generated by increasing the area of the signal lines is reduced. In the modification shown in FIG. 10, the first reflection layer 331 is arranged in a layer different from that of signal lines 334 in the wiring structure 302. This arrangement is also advantageous in reducing a timing jitter. In the modification shown in FIG. 11, the first reflection layer 331 is arranged in a second substrate 303 formed by a second wiring structure 305 and a second semiconductor layer 304. This arrangement is advantageous in increasing the distance L1 and detecting infrared rays in a long wavelength band.

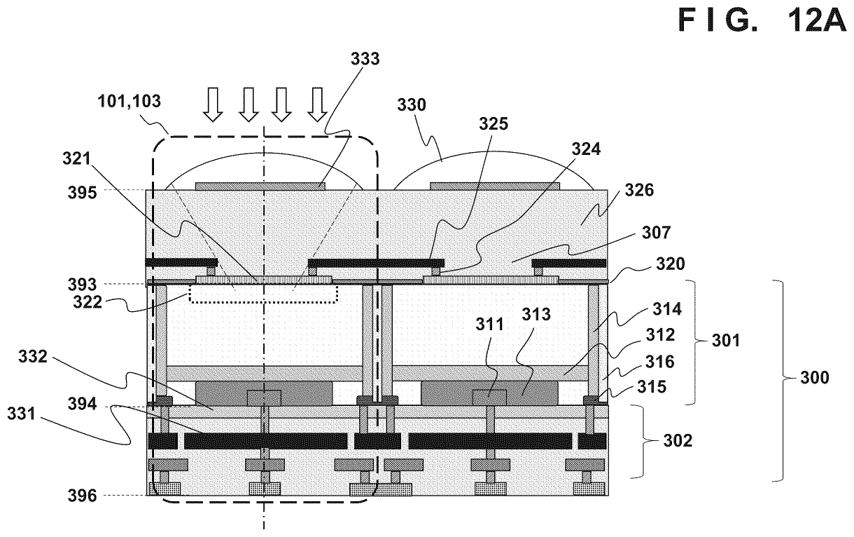

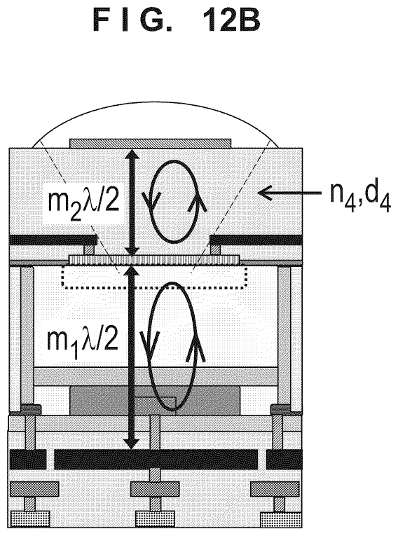

The third embodiment of the present disclosure will be described below. Matters not mentioned as the third embodiment can comply with the second embodiment. FIGS. 12A and 12B show the sectional structure of the arrangement of a photoelectric conversion apparatus 100 for two pixels according to third embodiment. FIG. 12A is a sectional view taken along a line A-A′ in FIG. 6. The photoelectric conversion apparatus 100 according to the third embodiment includes a second reflection layer 333. The second reflection layer 333 is arranged so that a first surface 393 is located between a second surface 394 and the second reflection layer 333. The second reflection layer 333 is a transparent member. The second reflection layer 333 is arranged between a light incident surface of the photoelectric conversion apparatus 100 and a first semiconductor layer 301. From another viewpoint, the second reflection layer 333 can be arranged between a microlens 330 and the first semiconductor layer 301. From still another viewpoint, the second reflection layer 333 can be arranged so that a sealing layer 326 is located between the second reflection layer 333 and the first semiconductor layer 301. For example, the second reflection layer 333 can be arranged to contact a third surface 395 as the surface of the sealing layer 326.

In this example, the distance between an electrode film 321 and the second reflection layer 333 is represented by L2, and an optical path length corresponding to it is represented by l2. The photoelectric conversion apparatus 100 according to the third embodiment is configured to satisfy the following equations. If the sealing layer 326 is made of a plurality of dielectric materials, an optical film thickness can be decided by the same method as in the second embodiment. By deciding the optical path length between the second reflection layer 333 and the electrode film 321 within the range of l2±λ/8, similar to a first reflection layer 331, it is possible to obtain an appropriate effect.

In a case where reflection by the above-described first reflection layer 331 is used or a case where light of a given specific wavelength is intentionally weakened, the optical path length l2 may be decided to match m₂×λ/4.

$$L 2 = {d}_{4}$$

$$l 2 = {m}_{2} \times λ / 2 = {d}_{4} \times {n}_{4}$$

d₄: film thickness of sealing layer 326
n₄: refractive index of sealing layer 326
m₂: natural number
λ: wavelength
L2: distance between second reflection layer 333 and electrode film 321
l2: optical path length between second reflection layer 333 and electrode film 321

For the sealing layer 326, for example, a dielectric such as SiO₂, SiNx, SiON, TiN, TiO₂, HfO₂, SiC, or Al₂O₃ or an organic dielectric film made of polyimide, BCB, or a cyclo-olefin resin, in one embodiment, is used, and the film thickness can be about 0.1 to 30 μm. If L1 and L2 are decided to satisfy l1=l2=m₁×λ/4=m₂×λ/4, the position of the electrode film 321 coincides with the position of the antinode of incident light having the wavelength λ, and thus the amplitude is maximum, thereby making it possible to maximize photoelectric conversion efficiency. In addition, the wavelength band in which light can be received may be extended by changing (λ1≠λ2) the wavelengths of light beams that strengthen each other between the first reflection layer 331 and the second reflection layer 333.

In one embodiment, the second reflection layer 333 is semi-transparent or transparent (transmittance of, for example, about 1% to 100%) at the wavelength of received light, similar to the electrode film 321. Therefore, the thickness of the first reflection layer 331 can be set to be equal to or smaller than a wavelength λ of received light and equal to or smaller than λ/10. The thickness of the first reflection layer 331 can typically be adjusted to a thickness of 100 nm or less. As the material of the second reflection layer 333, the above-described oxide semiconductor such as ITO or ZnO, which is known as a transparent electrode material, can be used. For the second reflection layer 333, the material and structure can be decided to have a transmittance higher than that of the first reflection layer 331.

In one design example, the sealing layer 326 is designed as silicon nitride SiNx (d₄=250 nm and n₂=2.00) by assuming a wavelength of 1 μm. In this case, m₂=1 is obtained and a λ/2 resonator is formed, thereby causing light beams to strengthen each other near the electrode film 321. Therefore, the position of the antinode of the standing wave of light having a wavelength of 1 μm coincides with the position of the electrode film 321. Thus, the light having a wavelength of 1 μm is selectively, strongly received, thereby increasing sensitivity at this wavelength. In a case where the wavelength is 1.5 μm or 2 μm, the thickness of the sealing layer 326 is set to d₄=380 nm or 500 nm, thereby forming a λ/2 resonator with m₂=1.

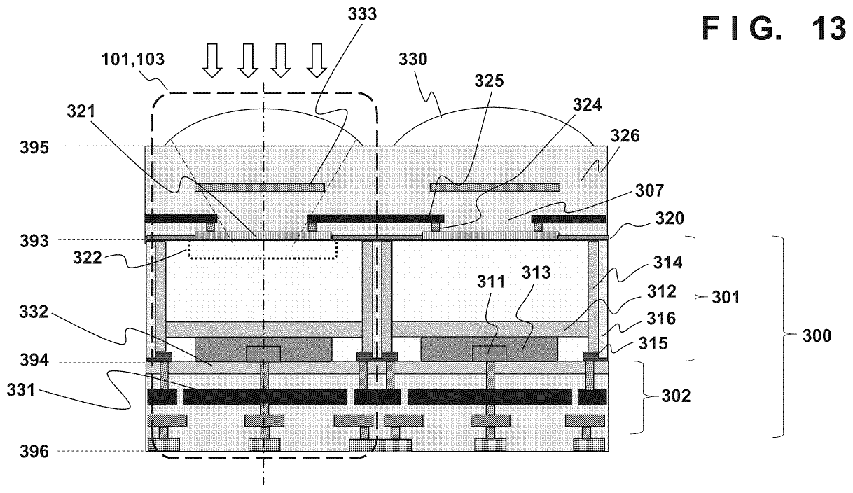

FIG. 13 shows another arrangement example according to the third embodiment. As exemplified in FIG. 13, the second reflection layer 333 may be arranged in the sealing layer 326. The position of the second reflection layer 333, that is, the distance L2 between the electrode film 321 and the second reflection layer 333 can be adjusted in accordance with the wavelength λ at which the light beams strengthen each other.

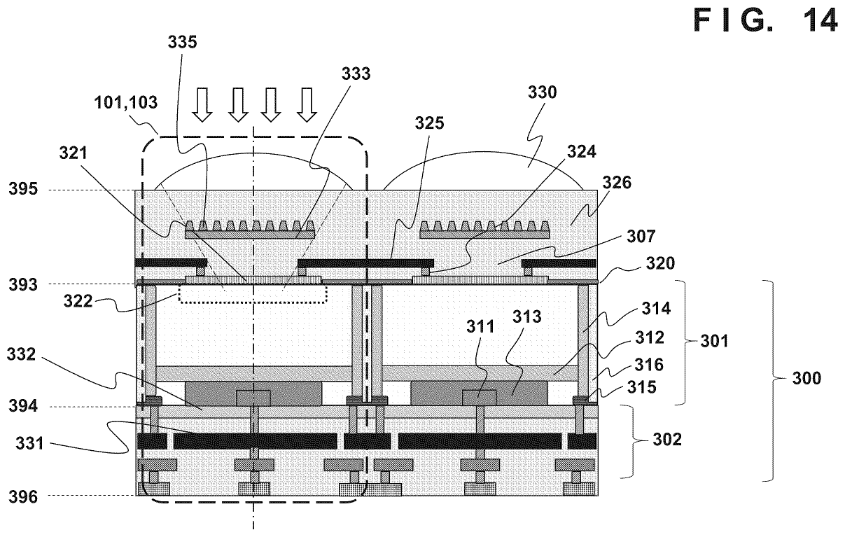

FIG. 14 shows still another arrangement example according to the third embodiment. As exemplified in FIG. 14, the second reflection layer 333 has an antireflection structure on the surface which light enters from the outside. The antireflection structure can include, for example, a sub-wavelength structure. From another viewpoint, the antireflection structure can include an uneven structure. From another viewpoint, the antireflection structure can include an antireflection film.

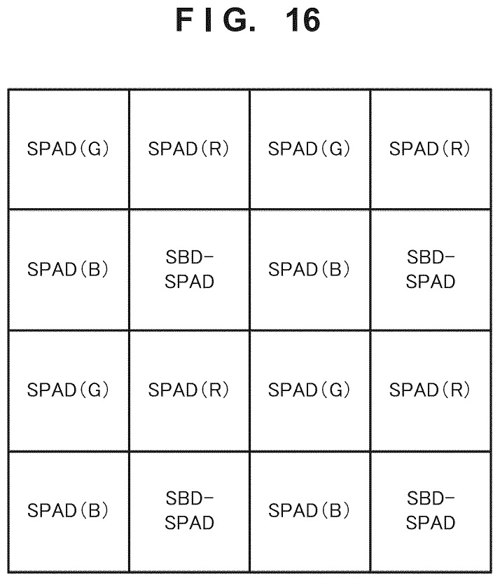

FIG. 16 exemplifies a pixel array in a photoelectric conversion apparatus 100 according to the fourth embodiment of the present disclosure. Matters not mentioned as the fourth embodiment can comply with each of the first to third embodiments. The photoelectric conversion apparatus 100 according to the fourth embodiment includes a plurality of pixels, and the plurality of pixels can include at least one first pixel and at least one second pixel. The at least one first pixel includes an avalanche photodiode 201 and a Schottky barrier diode 221, like the pixel in the photoelectric conversion apparatus 100 according to each of the first to third embodiments. On the other hand, the at least one second pixel includes the second avalanche photodiode arranged in a first semiconductor layer 301 but includes no Schottky barrier diode.

In the example shown in FIG. 16, the photoelectric conversion apparatus 100 includes, as the at least one first pixel, a pixel SBD-SPAD including the avalanche photodiode 201 and the Schottky barrier diode 221. In the example shown in FIG. 16, the photoelectric conversion apparatus 100 includes, as the at least one second pixel, a pixel SPAD(R) having sensitivity to light in a red wavelength range, a pixel SPAD(G) having sensitivity to light in a green wavelength range, and a pixel SPAD(B) having sensitivity to light in a blue wavelength range. To give sensitivity to visible light, the first semiconductor layer 301 can be formed to have a thickness of, for example, 3 to 6 μm. In an example, the photoelectric conversion apparatus 100 includes a plurality of pixel blocks arrayed in a matrix, and each pixel block can be formed by the pixels SPD-SPAD having sensitivity to the infrared range and the pixels SPAD(R), SPAD(G), and SPAD(B) each having sensitivity to the visible light range.

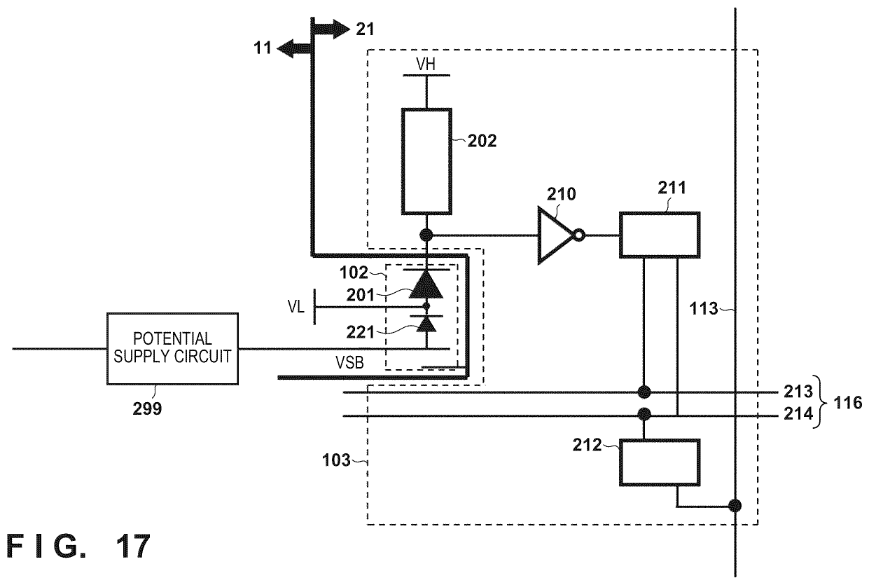

FIG. 17 exemplifies a pixel array in a photoelectric conversion apparatus 100 according to the fifth embodiment of the present disclosure. FIG. 17 shows an example of the arrangement of a pixel 101 and a signal processing unit 103 in the photoelectric conversion apparatus 100 according to the fifth embodiment. Matters not mentioned as the fifth embodiment can comply with each of the first to fourth embodiments. The photoelectric conversion apparatus 100 according to the fifth embodiment includes a potential supply circuit 299 that supplies a potential to an electrode film 321 of a Schottky barrier diode 221, and the potential supply circuit 299 supplies, to the electrode film 321, a potential corresponding to a mode selected from a plurality of modes.

In an example, the plurality of modes can include the first mode and the second mode. The first mode can be a mode of capturing the visible light range and the infrared range, and the second mode can be a mode of capturing only the visible light range. In the first mode, the potential supply circuit 299 can supply the first mode potential to the electrode film 321. In the second mode, the potential supply circuit 299 can supply the second mode potential lower than the first mode potential to the electrode film 321. The first mode potential is, for example, 1 V, and the second mode potential is, for example, 0 V. The first mode potential is decided to operate the Schottky barrier diode 221, and the second mode potential is decided not to operate the Schottky barrier diode 221.

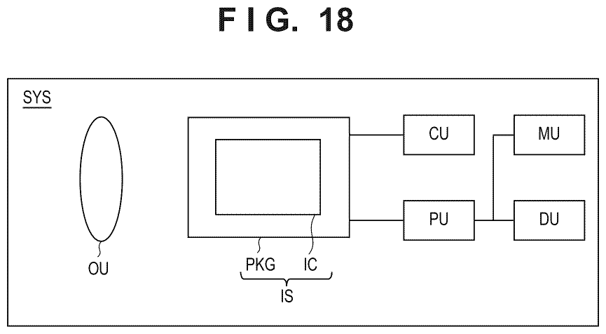

A photoelectric conversion system incorporating the photoelectric conversion apparatus exemplarily described through each of the above embodiments will exemplarily be described below. FIG. 18 shows an example of the photoelectric conversion system. The photoelectric conversion apparatus described in each of the above embodiments is applicable to various photoelectric conversion systems. Examples of the applicable photoelectric conversion systems are a digital still camera, a digital camcorder, a monitoring camera, a copying machine, a facsimile apparatus, a mobile phone, an in-vehicle camera, and an observation satellite. A camera module including an image capturing apparatus and an optical system such as a lens is also included in the photoelectric conversion systems.

The photoelectric conversion system is formed as, for example, an image capturing system SYS. The image capturing system SYS is a camera or an information terminal having an imaging function. An image capturing apparatus IS can further include a package PKG accommodating the photoelectric conversion apparatus 100 formed as an image capturing device IC. The package PKG can include a base on which the image capturing device IC is fixed, a cover facing the image capturing device IC, and a connection member for connecting a terminal of the base and a terminal of the image capturing device IC. The image capturing apparatus IS can arrange and mount the plurality of image capturing devices IC on the common package PKG. The image capturing apparatus IS can also stack and mount the image capturing device IC and another semiconductor device IC on the common package PKG.

The image capturing system SYS can include an optical system OU that forms an image on the image capturing apparatus IS. The image capturing system SYS can include at least one of a control apparatus CU that controls the image capturing apparatus IS, a processing apparatus PU that processes a signal obtained from the image capturing apparatus IS, and a display apparatus DU that displays an image obtained from the image capturing apparatus IS. Furthermore, the image capturing system SYS may include a storage apparatus MU that stores the image obtained from the image capturing apparatus IS.

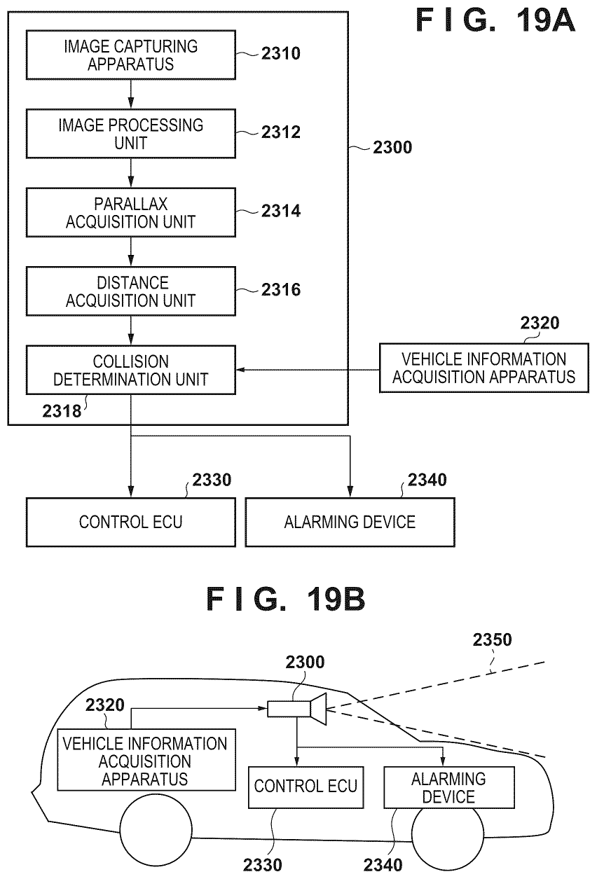

FIG. 19A exemplifies the configuration of a photoelectric conversion system applied to an in-vehicle camera. A photoelectric conversion system 2300 can include the photoelectric conversion apparatus 100 formed as an image capturing apparatus 2310. The photoelectric conversion system 2300 includes an image processing unit 2312 that performs image processing for a plurality of image data acquired by the image capturing apparatus 2310, and a parallax acquisition unit 2314 that calculates a parallax (the phase difference between parallax images) from the plurality of image data acquired by the photoelectric conversion system 2300. The photoelectric conversion system 2300 also includes a distance acquisition unit 2316 that calculates the distance up to a target object based on the calculated parallax, and a collision determination unit 2318 that determines, based on the calculated distance, whether there is collision possibility. Here, the parallax acquisition unit 2314 and the distance acquisition unit 2316 are examples of a distance information acquisition unit that acquires distance information up to a target object. That is, the distance information is information concerning a parallax, a defocus amount, a distance up to a target object, and the like.

The collision determination unit 2318 may determine collision possibility using one of the pieces of distance information. The distance information acquisition unit may be implemented by exclusively designed hardware, or may be implemented by a software module. The distance information acquisition unit may be implemented by a Field Programmable Gate Array (FPGA) or Application Specific Integrated Circuit (ASIC), or may be implemented by a combination of these.

The photoelectric conversion system 2300 is connected to a vehicle information acquisition apparatus 2320, and can acquire vehicle information such as a vehicle speed, a yaw rate, and a steering angle. The photoelectric conversion system 2300 is also connected to a control ECU 2330 that is a control unit configured to output a control signal for generating a braking force to the vehicle based on the determination result of the collision determination unit 2318. Furthermore, the photoelectric conversion system 2300 is connected to an alarm device 2340 that generates an alarm to the driver based on the determination result of the collision determination unit 2318. For example, if collision possibility is high as the determination result of the collision determination unit 2318, the control ECU 2330 performs vehicle control of braking, releasing the accelerator pedal, or suppressing the engine output, thereby avoiding collision and reducing damage. The alarm device 2340 sounds an alarm, displays alarming information on the screen of a car navigation system or the like, or applies a vibration to the seat belt or a steering wheel, thereby making an alarm to the user. In this embodiment, the periphery of the vehicle, for example, the front or rear side is captured by the photoelectric conversion system 2300.

FIG. 19B shows the photoelectric conversion system configured to capture the front side (image capturing range 2350) of the vehicle. The vehicle information acquisition apparatus 2320 sends an instruction to the photoelectric conversion system 2300 or the image capturing apparatus 2310. With this configuration, it is possible to further improve the accuracy of distance measurement.

An example in which control is executed so as not to collide with another vehicle has been explained above. The system can also be applied to control of performing automated driving following another vehicle or control of performing automated driving without deviating from a lane. Furthermore, the photoelectric conversion system can be applied not only to a vehicle such as an automobile but also to, for example, a moving body (moving apparatus) such as a ship, an airplane, or an industrial robot. In addition, the photoelectric conversion system can be applied not only to a moving body but also to an apparatus that broadly uses object recognition, such as an intelligent transport system (ITS).

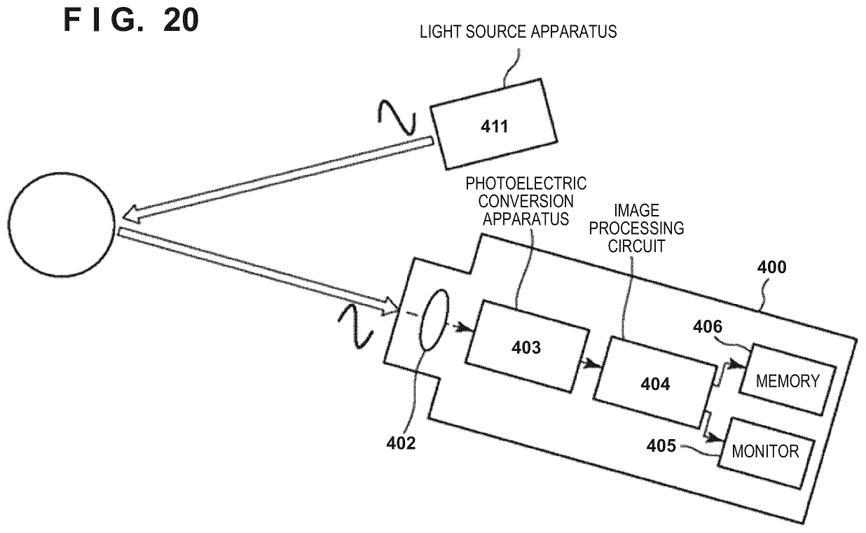

FIG. 20 exemplifies the configuration of a photoelectric conversion system formed as a distance image sensor. A distance image sensor 400 includes an optical system 407, a photoelectric conversion apparatus 408, an image processing circuit 404, a monitor 405, and a memory 406. Then, the distance image sensor 400 can receive light (modulated light or pulsed light) projected from a light source apparatus 409 toward an object and reflected by the surface of the object, thereby acquiring a distance image corresponding to the distance up to the object.

The optical system 407 is formed by including one or a plurality of lenses, and guides image light (incident light) from the object to the photoelectric conversion apparatus 408 and forms an image on the light-receiving surface (sensor portion) of the photoelectric conversion apparatus 408. As the photoelectric conversion apparatus 408, the photoelectric conversion apparatus of each of the above-described embodiments is applied, and a distance signal indicating a distance obtained from a light reception signal output from the photoelectric conversion apparatus 408 is supplied to the image processing circuit 404.

The image processing circuit 404 performs image processing of creating a distance image based on the distance signal supplied from the photoelectric conversion apparatus 408. Then, the distance image (image data) obtained by the image processing is supplied to and displayed on the monitor 405, and supplied to and stored (recorded) in the memory 406. The distance image sensor 400 having such arrangement can acquire, for example, a more correct distance image along with improvement in characteristic of pixels by applying the above-described photoelectric conversion apparatus.

According to the aspect of the embodiments, there is provided a technique advantageous in improving sensitivity to the infrared range in a photoelectric conversion apparatus including an avalanche photodiode.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-083185, filed May 19, 2023, which is hereby incorporated by reference herein in its entirety.

What is claimed is:

1. A photoelectric conversion apparatus comprising:
a semiconductor layer having a first surface and a second surface;
an avalanche photodiode arranged in the semiconductor layer;
an electrode film arranged to contact the first surface such that a Schottky barrier diode is formed in a contact portion with the semiconductor layer; and
a wiring structure arranged on a side of the second surface.

2. The apparatus according to claim 1, wherein light from an outside enters the semiconductor layer via the first surface.

3. The apparatus according to claim 2, wherein the avalanche photodiode is arranged between the second surface and the Schottky barrier diode.

4. The apparatus according to claim 2, wherein in an orthogonal projection to the second surface, the avalanche photodiode and the Schottky barrier diode overlap each other.

5. The apparatus according to claim 2, wherein the avalanche photodiode and the Schottky barrier diode are series-connected via a depletion region.

6. The apparatus according to claim 2, wherein the wiring structure includes a first reflection layer configured to reflect light having passed through the semiconductor layer and entering the wiring structure.

7. The apparatus according to claim 6, wherein the wiring structure includes an insulating layer arranged between the second surface and the first reflection layer.

8. The apparatus according to claim 6, wherein
in a case where λ represents a wavelength of the light entering from the outside and m₁ represents a natural number, an optical path length between the electrode film and the first reflection layer is given by m₁×λ/2±λ/8.

9. The apparatus according to claim 6, wherein a dimension of the first reflection layer in a direction along the second surface is larger than a dimension of the electrode film in the direction along the second surface.

10. The apparatus according to claim 6, wherein
the avalanche photodiode includes a first semiconductor region of a first conductivity type, a second semiconductor region of a second conductivity type, and a third semiconductor region of the first conductivity type arranged between the second surface and the second semiconductor region,
the third semiconductor region includes a portion arranged between the second surface and the second semiconductor region to surround a side surface of the first semiconductor region, and a portion arranged between the first semiconductor region and the second semiconductor region, and
a dimension of the first reflection layer in a direction along the second surface is larger than a dimension of the third semiconductor region in the direction along the second surface.

11. The apparatus according to claim 6, further comprising a light shielding film,
wherein the light shielding film is arranged so that the first surface is located between the second surface and the light shielding film,
the light shielding film includes an opening that defines light entering the Schottky barrier diode, and
a dimension of the first reflection layer in a direction along the second surface is larger than a dimension of the opening in the direction along the second surface.

12. The apparatus according to claim 6, further comprising a second reflection layer,
wherein the second reflection layer is arranged so that the first surface is located between the second surface and the second reflection layer.

13. The apparatus according to claim 12, wherein
in a case where λ represents a wavelength of the light entering from the outside and m₂ represents a natural number, an optical path length between the electrode film and the second reflection layer is given by m₂×λ/2±λ/8.

14. The apparatus according to claim 12, wherein
in a case where λ represents a wavelength of the light entering from the outside and m₁ and m₂ represent natural numbers,
an optical path length between the electrode film and the first reflection layer is given by m₁×λ/4, and
an optical path length between the electrode film and the second reflection layer is given by m₂×λ/4.

15. The apparatus according to claim 12, wherein the second reflection layer has an antireflection structure on a surface which the light enters from the outside.

16. The apparatus according to claim 12, further comprising a sealing layer arranged between the semiconductor layer and the second reflection layer.

17. The apparatus according to claim 16, further comprising a microlens arranged to cover the second reflection layer.

18. The apparatus according to claim 12, further comprising a sealing layer,
wherein the sealing layer is arranged so that the first surface is located between the second surface and the sealing layer,
the sealing layer has a third surface on an opposite side of the first surface, and
the second reflection layer is arranged in the sealing layer.

19. The apparatus according to claim 18, further comprising a microlens arranged to cover the second reflection layer.

20. The apparatus according to claim 1, wherein
the avalanche photodiode includes a first semiconductor region of a first conductivity type, a second semiconductor region of a second conductivity type, and a third semiconductor region of the first conductivity type arranged between the second surface and the second semiconductor region, and
the third semiconductor region includes a portion arranged between the second surface and the second semiconductor region to surround a side surface of the first semiconductor region, and a portion arranged between the first semiconductor region and the second semiconductor region.

21. The apparatus according to claim 20, wherein in a planar view, an area of the first semiconductor region is smaller than an area of the electrode film.

22. The apparatus according to claim 20, wherein
a first potential is supplied to the second semiconductor region,
a second potential is supplied to the first semiconductor region,
a third potential is supplied to the electrode film, and
a potential becomes higher in an order of the third potential, the first potential, and the second potential.

23. The apparatus according to claim 20, further comprising a fourth semiconductor region of the second conductivity type electrically connected to the second semiconductor region and extending between the first surface and the second surface in a direction orthogonal to the first surface,
wherein a potential is applied to the second semiconductor region via the fourth semiconductor region.

24. The apparatus according to claim 23, wherein the fourth semiconductor region is arranged to surround the first semiconductor region, the second semiconductor region, and the third semiconductor region.

25. The apparatus according to claim 24, further comprising a fifth semiconductor region of the second conductivity type arranged between the second surface and the fourth semiconductor region.

26. The apparatus according to claim 25, further comprising a pinning film configured to cover the first surface to surround the electrode film.

27. The apparatus according to claim 1, further comprising a plurality of pixels,
wherein the plurality of pixels includes at least one first pixel and at least one second pixel,
the at least one first pixel includes the avalanche photodiode and the Schottky barrier diode, and
the at least one second pixel includes a second avalanche photodiode arranged in the semiconductor layer, and includes no Schottky barrier diode.

28. The apparatus according to claim 27, wherein the at least one second pixel includes a pixel having sensitivity to light in a red wavelength range, a pixel having sensitivity to light in a green wavelength range, and a pixel having sensitivity to light in a blue wavelength range.

29. The apparatus according to claim 1, further comprising a potential supply circuit configured to supply a potential to the electrode film of the Schottky barrier diode,
wherein the potential supply circuit supplies, to the electrode film, a potential corresponding to a mode selected from a plurality of modes.

30. A photoelectric conversion system comprising:
the photoelectric conversion apparatus defined in claim 1; and
a signal processing unit configured to process a signal output from the photoelectric conversion apparatus.
